(19) United States
(12) Patent Application Publication
(10) Pub. No.: US 2011/0228460 A1
(43) Pub. Date: Sep. 22, 2011

(54) GASKET AND DISPLAY APPARATUS USING THE SAME

(76) Inventors: You-Hoon Kim, Woodbury, MN (US); Ha-Young Lee, Seoul (KR); Sung-Won Ha, Seoul (KR); Do-Kwang Cho, Gyeonggi-do (KR)

(21) Appl. No.: 13/119,844

(22) PCT Filed: Sep. 17, 2009
(86) PCT No.: PCT/US09/57329

§ 371 Date: Jun. 13, 2011

(30) Foreign Application Priority Data
Sep. 18, 2008 (KR) 10-2008-0091677

(51) Int. Cl. H05K 7/00; F16J 15/10; F16J 15/06; C08F 2/48

(52) U.S. Cl. 361/679.01; 277/637; 427/493

(57) ABSTRACT

Disclosed is a gasket comprising a support layer; a blocking pad layer laminated on one side of the support layer and made of an acrylic polymer resin composition; and an adhesive layer laminated on the other side of the support layer and made of an adhesive polymer resin. The acrylic polymer resin composition comprises a urethane acrylate oligomer; a first acrylic monomer; a second acrylic monomer having a higher glass transition temperature than the first acrylic monomer; and a filler.

### FIELD

The present disclosure relates to gaskets, including gaskets for use in a display apparatus.

### BACKGROUND

With the rapid growth of electric/electronic technology, all kinds of electronic equipment, such as personal computers, televisions, digital billboards, cellular phones, digital cameras, and electronic calculators have also been rapidly developed in recent years. In line with this, various display apparatuses (e.g. LCD, PDP, LED, CRT, etc.)

performing an image display function for electronic equipment have become increasing important.

In general, a display apparatus may include an image display module for displaying images; and frames for mechanically/physically protecting/supporting the image display module. For example, a display apparatus may include a front frame; a rear frame; and an image display module disposed between the front and rear frames, and if necessary, may further include a guide frame disposed around the edge of the rear frame.

In such a display apparatus, a gasket is disposed around the edge of the front frame, and/or may be disposed around the edge of the rear frame. In some cases, a gasket may be disposed on a part of the surface of the guide frame or the image display module.

The gasket may perform a function of protecting the image display module and the like from external shocks and vibrations, a function of blocking external light beams from entering the image display module, a function of intercepting light leakage when the image display module or/and the frames is/are bent by external forces, and other functions.

A silicone gasket has been used as such a gasket for use in a display apparatus. Since the silicone gasket has cushion and anti-slip properties, it can not only protect an image display module from external shocks and vibrations, but also suppress the image display module from moving by external forces.

However, the silicone gasket has a low adhesive strength to a typical pressure-sensitive adhesive (e.g. acrylic adhesive) or double-sided tape (e.g. acrylic double-sided tape). On account of this, when the silicone gasket is attached to a display apparatus by means of a typical pressure-sensitive adhesive or double-sided tape, there is a problem in that the silicone gasket is easily peeled from the display apparatus. To solve this problem, a silicone gasket has been applied to a display apparatus (e.g. frame) 100 by using a silicone/acrylic double-sided tape 30, as illustrated in FIG. 1; wherein, double-sided tape 30 consists of adhesive layers 31 on opposite sides of substrate 32.

However, since the adhesive strength of the silicone/acrylic double-sided tape is lower than that of a typical pressure-sensitive adhesive or double-sided tape, there is still the problem of peeling of a silicone gasket from a display apparatus. Furthermore, the silicone gasket or silicone/acrylic double-sided tape is expensive, which causes an increase in the manufacturing cost of a display apparatus.

Attempts have been made to replace the conventional silicone gasket with a polyurethane foam gasket that has a good adhesive strength to a typical pressure-sensitive adhesive or double-sided tape and is inexpensive. However, although the polyurethane foam gasket is excellent in cushion property for shock and vibration absorption, it has a poor anti-slip property.

Therefore, there is now a need to develop a new gasket as substitute for a silicone gasket or polyurethane foam gasket.

### SUMMARY

In one aspect, the present disclosure provides a gasket comprising a support layer; a blocking pad layer on one side of the support layer and an adhesive layer on the other side of the support layer. The support layer comprises an acrylic polymer resin composition, wherein the acrylic polymer resin composition comprises a urethane acrylate oligomer; a first acrylic monomer; a second acrylic monomer having a higher glass transition temperature than the first acrylic monomer; and a filler. The adhesive layer comprises an adhesive polymer resin.

In some embodiments, a surface of the the blocking pad layer comprises a plurality of continuous or discontinuous concavo-convex projection patterns. In some embodiments, the projection patterns have a height of 0.3 to 100 microns.

In some embodiments, the adhesive strength is sufficient to fix a glass plate with a weight of 80 g in an inclination range of 90° without any movement when the glass plate is disposed on a strip of the gasket, having an area of 2 mm×40 mm.

In some embodiments, the urethane acrylate oligomer has a number average molecular weight of 5,000 to 100,000. In some embodiments, the acrylic polymer resin composition comprises an acrylic monomer having a C6 to C12 alkyl group. In some embodiments, the first acrylic monomer has a glass transition temperature of −80 to 0° C., and the second acrylic monomer has a glass transition temperature of 60 to 120° C. In some embodiments, the acrylic polymer resin composition comprises the first and second acrylic monomers in a weight ratio of 95-60:5-40.

In some embodiments, the acrylic polymer resin composition comprises: 60 to 95 parts by weight of the first acrylic monomer; 5 to 40 parts by weight of the second acrylic monomer; 5 to 80 parts by weight of the urethane acrylate oligomer; and 0.1 to 100 parts by weight of the filler, based on 100 parts by weight of the mixture of the first and second acrylic monomer.

In some embodiments, the support layer comprises a polyethylene terephthalate film. In some embodiments, the polyethylene terephthalate film contains a black pigment.

In some embodiments, the adhesive polymer resin comprises an acrylic polymer resin. In some embodiments, the gasket further comprising a release film laminated on the side of the adhesive layer opposite the support layer.

In another aspect, the present disclosure provides a display apparatus comprising: an image display module; at least one frame; and a gasket according to any embodiment of the present disclosure disposed on at least one of at least a partial surface of the image display and at least a partial surface of the frame

In yet another aspect, the present disclosure provides a method of manufacturing a gasket, the method comprising the steps of: applying an acrylic polymer resin composition onto one side of a support layer; curing the acrylic polymer resin composition applied onto the support layer to thereby form a blocking pad layer; and applying adhesive polymer resin syrup onto the other side of the support layer with the blocking layer laminated on the one side thereof and then curing the adhesive polymer resin syrup to thereby form an adhesive layer, wherein the step of curing the acrylic polymer resin composition comprises a first step of irradiating ultraviolet rays having an intensity of 2 to 10 mW/cm2; and a seconds step of irradiating ultraviolet rays having an intensity of 30 to 50 mW/cm2.

In some embodiments, the first step of irradiating ultraviolet rays comprises the steps of: irradiating ultraviolet rays having an intensity of 2 to 4 mW/cm2; irradiating ultraviolet rays having an intensity of 4 to 6 mW/cm2; and irradiating ultraviolet rays having an intensity of 7 to 9 mW/cm2.

### BRIEF DESCRIPTION OF THE DRAWINGS

FIG. 1 is a view illustrating a way to apply a silicone gasket known in the art to a display apparatus using a double-sided tape.

FIG. 2 is a sectional view of a gasket according to an embodiment of the present disclosure.

FIG. 3 is a sectional view of a gasket according to another embodiment of the present disclosure.

FIG. 4 is a exploded view of a display apparatus to which a gasket according to an embodiment of the present disclosure is applied before a front frame, an image display module, and a rear frame are not assembled.

FIG. 5 is a graph illustrating the pattern level formed on the surface of a blocking pad layer depending on the contents of a urethane acrylate oligomer, a first acrylic monomer, and a filler.

FIGS. 6(a)-6(e) are a series of pictures illustrating surfaces of gaskets manufactured in Examples 1 to 5.

FIG. 7 is a surface and sectional view of a gasket manufactured in Example 4, taken along line A-A′.

FIG. 8 is a surface and sectional view of a gasket manufactured in Example 5, taken along line B-B′.

FIG. 9 is an illustration of measuring whether or not a glass plate slips down, according to (1) of Experimental Example 1.

FIG. 10 is an illustration of measuring whether or not a glass plate slips down, according to (2) of Experimental Example 1.

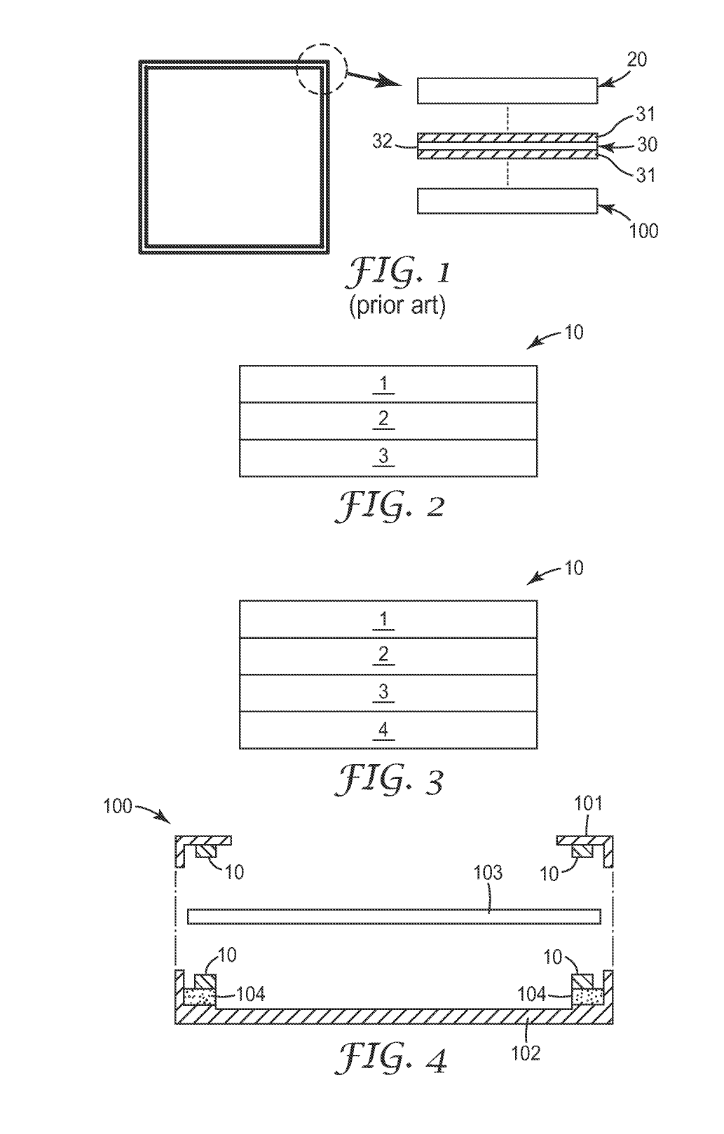

### DETAILED DESCRIPTION

The present disclosure is directed to a gasket having cushion and tack properties, which is provided by forming an adhesive layer on one side of a support member and forming a blocking pad layer on the other side of the support member by use of an acrylic polymer resin composition comprising a urethane acrylate oligomer; and first and second acrylic monomers having different glass transition temperatures.

According to an aspect of the present disclosure, there is provided a gasket including: a support layer; a blocking pad layer laminated on one side of the support layer and made of an acrylic polymer resin composition; and an adhesive layer laminated on the other side of the support layer and made of an adhesive polymer resin, wherein, the acrylic polymer resin composition comprises a urethane acrylate oligomer; a first acrylic monomer; a second acrylic monomer having a higher glass transition temperature than the first acrylic monomer; and a filler. The present disclosure also provides a display apparatus comprising the above gasket.

According to another aspect of the present disclosure, there is provided a method of manufacturing a gasket, the method comprising the steps of: applying an acrylic polymer resin composition onto one side of a support layer; curing the acrylic polymer resin composition applied onto the support layer to thereby form a blocking pad layer; and applying adhesive polymer resin syrup onto the other side of the support layer with the blocking layer laminated on the one side thereof and then curing the adhesive polymer resin syrup to thereby form an adhesive layer, wherein the step of curing the acrylic polymer resin composition comprises a first step of irradiating ultraviolet rays having an intensity of 2 to 10 mW/cm² and a seconds step of irradiating ultraviolet rays having an intensity of 30 to 50 mW/cm².

In some embodiments, the present disclosure can provide a cost-effective gasket having cushion and tack properties by forming an adhesive layer on one side of a support member and forming a blocking pad layer on the other side of the support member by use of an acrylic polymer resin composition comprising a urethane acrylate oligomer, and first and second acrylic monomers having different glass transition temperatures.

Reference will now be made in detail to various embodiments of the present disclosure.

In general, a gasket for use in a display apparatus is used to protect the display apparatus from external shocks and vibrations, block external light beams from entering an image display module, prevent light leakage from the inside when frames or the like are bent, and so forth. To this end, a gasket should have superior cushion and anti-slip properties.

Accordingly, in some embodiments of the present disclosure, a gasket is formed with a blocking pad layer made of an acrylic polymer resin composition comprising a urethane acrylate oligomer; a first acrylic monomer; a second acrylic monomer having a higher glass transition temperature than the monomer; and a filler. In some embodiments, a plurality of continuous or discontinuous projection patterns are formed on the surface of the blocking pad layer, and simultaneously the blocking pad layer has a tack property, which makes it possible to improve the cushion and anti-slip properties of the resultant gasket.

More specially, in some embodiments, the gasket of the present disclosure includes a blocking pad layer, the surface of which is formed with a plurality of continuous or discontinuous projection patterns.

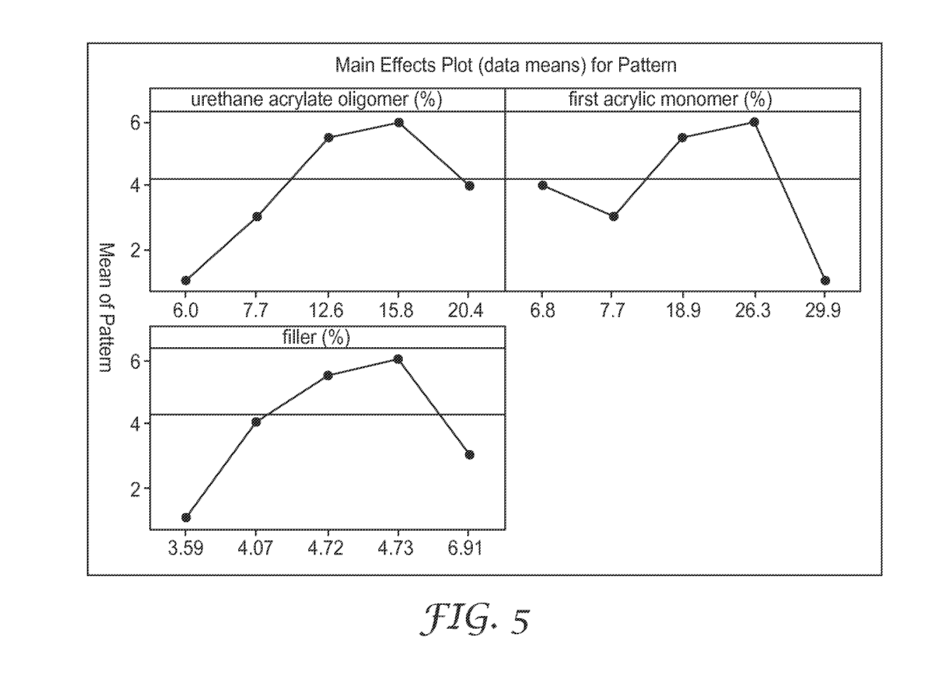

FIG. 5 is a main effects plot showing the mean height of the projection pattern as a function of each of the weight percent urethane acrylate oligomer, weight percent first acrylic monomer, and weight percent filler. As illustrated in FIG. 5, the projection patterns may be differently formed depending on the contents of the urethane acrylate oligomer, the first acrylic monomer, and the filler, and depending on the interactions between the urethane acrylate oligomer and the first acrylic monomer, between the urethane acrylate oligomer and the filler, and between the first acrylic monomer and the filler.

In this way, the projection patterns formed depending on the contents and interactions of the constituent components can provide the blocking pad layer with a high cushion property, as a result of which the gasket can protect a display apparatus from external shocks and vibrations. Additionally, since the projection patterns increase the surface area of the blocking pad layer, a close adhesion property between the gasket and a display apparatus can be improved.

Further, in some embodiments, the blocking pad layer of the gasket has a tack property. This tack property of the blocking pad layer may lead to improvements in the anti-slip property of the resultant gasket, and finally the resultant gasket can suppress the movements of a display apparatus. The tack property of the blocking pad layer may be adjusted according to the mixing ratio of the acrylic monomers in the acrylic polymer resin composition, which have different glass transition temperatures. More specially, while the first acrylic monomer having a lower glass transition temperature (e.g. isooctylacrylate) may increase the tack property of the blocking pad layer, the second acrylic monomer having a higher glass transition temperature (e.g. acrylic acid) may decrease the tack property of the blocking pad layer. On account of this, the blocking pad layer may have a desired tack property by adjusting the mixing ratio of the first and second acrylic monomer, and finally the resultant gasket can have a desired anti-slip property. Therefore, the gasket can suppress or minimize the movements of a display apparatus.

Further, the gasket includes an adhesive layer laminated on one side of a support layer and made of an adhesive polymer resin, and thereby may be disposed/fixed in a display apparatus without using a separate double-sided tape or pressure-sensitive adhesive, dissimilar to a conventional silicone gasket.

In this way, the gasket can be improved in cushion and tack properties by including the blocking pad layer made of an acrylic polymer resin composition and the adhesive layer made of an adhesive polymer resin. As such, the gasket can protect a display apparatus from external shocks and vibrations, and can suppress the movements of a display apparatus by external forces. Additionally, the gasket can block external light beams from entering an image display module, and at the same time, prevent light leakage from the inside when frames or the like are bent.

Referring to FIG. 2, according to an embodiment of the present disclosure, a gasket 10 includes a support layer 2; a blocking pad layer 1 laminated on one side of the support layer 2 and made of an acrylic polymer resin composition; and an adhesive layer 3 laminated on the other side of the support layer 2 and made of an adhesive polymer resin. Referring to FIG. 3, in some embodiments, the gasket 10 may further include a release film 4 laminated on other side of the adhesive layer 3 (i.e., the side of the adhesive layer 3 opposite the support layer 2).

When the gasket 10 is disposed in and attached to a display apparatus 100, as illustrated in FIG. 4, the blocking pad layer may substantially perform a function of protecting an image display module, a circuit module, and the like of the display apparatus from external shocks and vibrations, a function of blocking external light beams from entering the image display module, a function of intercepting light leakage when the image display module or/and frames is/are bent by external forces, and other functions. The blocking pad layer functioning in this way may have, but not limited to, a thickness of about 50 to 1,000 microns according to the specifications of a display apparatus. According to an embodiment of the present disclosure, the thickness of the blocking pad layer is about 350 microns.

The blocking pad layer is made of an acrylic polymer resin composition. The acrylic polymer resin composition includes a urethane acrylate oligomer; a first acrylic monomer; a second acrylic monomer having a higher glass transition temperature than the first acrylic monomer; and a filler, and may include a pigment, if necessary.

The urethane acrylate oligomer is formed by mixing and reacting diisocyanate with polyol in a reactor. This urethane acrylate oligomer may form a plurality of continuous or discontinuous projection patterns on the blocking pad layer. The projection patterns formed in this way can improve not only the cushion property of the blocking pad layer, but also increase the surface area of the blocking pad layer to thereby improve the close adhesion property of the blocking pad layer with respect to a display apparatus.

Examples of the diisocyanate include isophorone diisocyanate, 2,4-toluene diisocyanate and its isomers, hexamethylene diisocyanate, lysine diisocyanate, trimethylhexamethylene diisocyanate, 2,2-bis-4′-propane isocyanate, 6-isopropyl-1,3-phenyl diisocyanate, bis(2-isocyanateethyl)-fumarate, 1,6-hexane diisocyanate, 4,4′-biphenylene diisocyanate, 3,3′-dimethylphenylene diisocyanate, 3,3′-dimethyl-4,4′-diphenylmethane diisocyanate, p-phenylene diisocyanate, m-phenylene diisocyanate, 1,5-naphthalene diisocyanate, 1,4-xylene diisocyanate, 1,3-xylene diisocyanate, etc.

The polyol includes monomolecular diols, and its examples include ethylene glycol, propylene glycol, 1,3-butanediol, 1,4-butanediol, 1,5-pentanediol, 1,6-hexanediol, neopentylglicol, 1,4-cyclohexane dimethanol, bisphenol A, bisphenol F, reduced bisphenol A, reduced bisphenol F, dicyclopentanediol, tricyclodecanediol, etc. Also, the polyol that can be used in the present disclosure includes a compound having at least three hydroxyl groups in a molecule. Examples of the compound include glycerol, trimethylolethane, trimethylolpropane, pentaerythritol, sorbose, sorbitol, etc. Also, such the polyol can be used alone, or can be used by mixing at least two of these materials. Additionally, polyester polyol, polycarbonate polyol, polycaprolactone polyol, and the like may be used solely or in combination as the polyol, or a mixture of the monomolecular diols and polyester polyol, polycarbonate polyol, polycaprolactone polyol, etc. may also be used as the polyol.

Preferably, such polyol reacts with the above-mentioned diisocyanate to thereby form a urethane acrylate oligomer having a number average molecular weight of about 5,000 to 100,000. If the number average molecular weight of the urethane acrylate oligomer is less than 5,000, projection patterns are densely formed on the blocking pad layer, and an increase in crosslinking density is caused by a low molecular weight, which results in a relatively hard pad layer having a lowered cushion property. In addition, if the number average molecular weight of the urethane acrylate oligomer exceeds 100,000, patterns in an excessively expanded form are generated on the blocking pad layer of the gasket, and thus the surface of the blocking pad layer is almost flattened, which lowers the wettability or close adhesion property of the blocking pad layer to a display apparatus. Also, the viscosity of the urethane acrylate oligomer is increased by a high molecular weight, resulting in lowering of workability.

As illustrated in FIG. 5, since pattern formation on the blocking pad layer may be adjusted depending on the content of the urethane acrylate oligomer and thus the surface area of the blocking pad layer may be adjusted, it is preferred that the urethane acrylate oligomer has a content of about 5 to 80 parts by weight, based on 100 parts by weight of the mixture of the first and second acrylic monomer. If the content of the urethane acrylate oligomer is less than 5 parts by weight, pattern formation is insufficient and adhesive strength is too strong and thus the resultant gasket is unusable. Also, if the content of the urethane acrylate oligomer exceeds 80 parts by weight, excess in pattern formation may cause a hard pad layer.

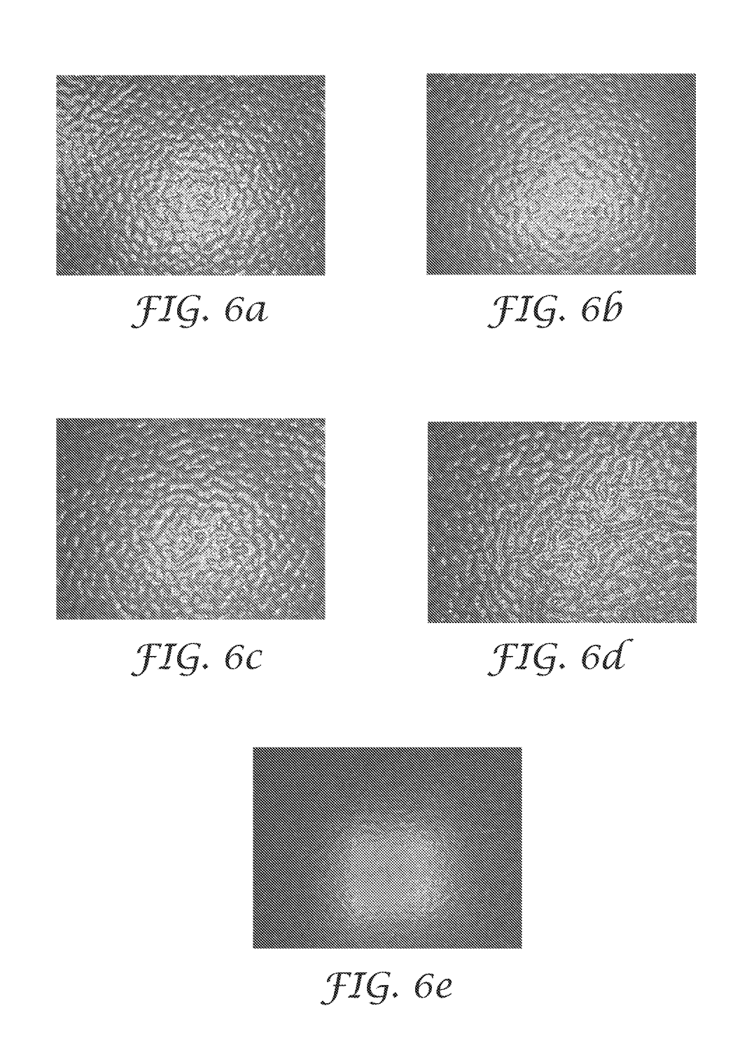

By such a urethane acrylate oligomer, a plurality of continuous or discontinuous concavo-convex projection patterns may be formed on the blocking pad layer, as illustrated in FIGS. 6(a)-6(e).

The overall shape of the projection patterns is similar to those formed on the surface of an orange (e.g., sometimes referred to as an “orange peel” pattern”), but this shape may be adjusted depending on the content of the urethane acrylate oligomer.

The height of the projection patterns may be adjusted depending on the content of the urethane acrylate oligomer and depending on the contents of other components of the acrylic polymer resin composition. However, since the cushion property of the blocking pad layer varies according to the height of the projection patterns, the projection patterns preferably has a height of about 0.3 to 100 microns.

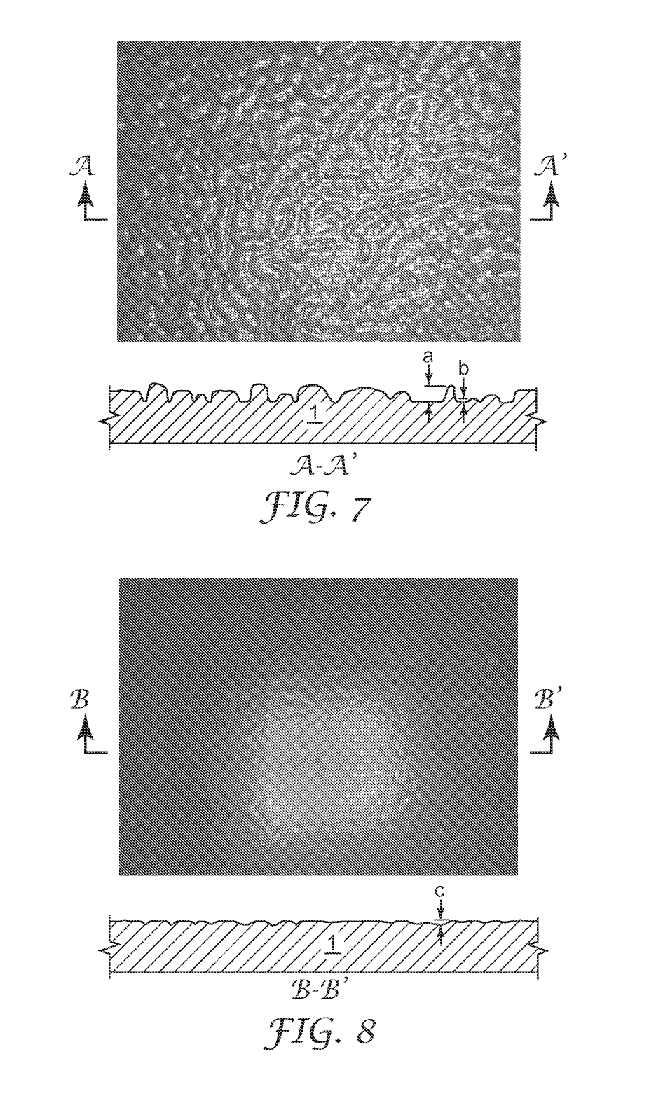

According to one embodiment of the present disclosure, when the content of the urethane acrylate oligomer is about 30 parts by weight, a blocking pad layer having projection patterns may be formed as illustrated in FIG. 7. Herein, the projection patterns may have a maximum height, a, of about 40 microns, and a minimum height, b, of about 1 micron.

According to another embodiment of the present disclosure, when the content of the urethane acrylate oligomer is about 10 parts by weight, a blocking pad layer having almost no projection pattern may be formed as illustrated in FIG. 8. Herein, the projection patterns may have a height of about 0.5 microns.

The acrylic polymer resin composition constituting the blocking pad layer includes two kinds of acrylic monomers having different glass transition temperatures, as well as the aforementioned urethane acrylate oligomer. To be specific, the acrylic polymer resin composition includes a first acrylic monomer, and a second acrylic monomer having a higher glass transition temperature than the first acrylic monomer. More specially, the acrylic polymer resin composition may include a first acrylic monomer having a glass transition temperature of about −80 to 0° C., and a second acrylic monomer having a glass transition temperature of about 60 to 120° C.

With regard to this, while the first acrylic monomer may provide the blocking pad layer with a high tack property, the second acrylic monomer may provide the blocking pad layer with a low tack property. That is, the level of the tack property of the blocking pad layer may be adjusted depending on the mixing ratio of the first and second acrylic monomers. According to an embodiment of the present invention, the first and second acrylic monomers may be included in a weight ratio of 95-60 for the first acrylic monomer to 5-40 for the second acrylic monomer (i.e., 95-60:5-40). In consideration of such a mixing ratio, the first acrylic monomer may be included in an amount of about 60 to 95 parts by weight, and the second acrylic monomer may be included in an amount of about 5 to 40 parts by weight, based on 100 parts by weight of the mixture of the first and second acrylic monomer.

Examples of the first acrylic monomer having a glass transition temperature of about −80 to 0° C. include C₆ to C₁₂ acrylic monomers. According to an example of the present disclosure, the first acrylic monomer may be a C₇˜C₉ acrylic monomer. More specific examples of the first acrylic monomer include, but not limited to, hexyl(meth)acrylate, n-octyl(meth)acrylate, isooctyl(meth)acrylate, 2-ethylhexyl(meth)acrylate, isononyl(meth)acrylate, etc.

The second acrylic monomer is an acrylic monomer having a higher glass transition temperature than the acrylic monomer, and its typical example includes a polar monomer copolymerizable with the first acrylic monomer. More specific examples of the second acrylic monomer include, but not limited to, a monomer containing a carboxyl group, such as (meth)acrylic acid, maleic acid, and fumaric acid, and a monomer containing nitrogen, such as acrylamide, dimethylacrylamide, N-vinyl pyrrolidone, and N-vinyl caprolactam.

The acrylic polymer resin composition may further include a glass bubble, fumed silica, etc. as a filler.

The glass bubble includes particles in the form of a bubble, the inside of which is vacant, and each particle has an independent bubble. Thus, the glass bubble can form a porous structure within the blocking pad layer, thereby not only increasing the cushion property of the blocking pad layer, but also improving the wettability of the blocking pad layer and consequently increasing close adhesion property between the resultant gasket and a display apparatus. To this end, the acrylic polymer resin composition of the present disclosure may include, in addition to the glass bubble, materials having similar forms and properties to the glass bubble, for example, resin bubbles, such as an epoxy resin bubbles, a polycarbonate resin bubble, etc.

There is no particular limitation on the particle diameter of the glass bubble-type filler, but a particle diameter of about 20 to 500 microns is preferred. If the particle diameter of the filler is less than 20 microns, even though a porous structure is formed within the blocking pad layer, a pore size formed within the blocking pad layer is too small to increase the cushion property of the blocking pad layer. Also, if the particle diameter of the filler exceeds 500 microns, the strength of the blocking pad layer may be lowered because the size of pores formed within the blocking pad layer of the resultant gasket is too large.

There is no particular limitation on the content of the glass bubble-type filler, but the filler preferably has a content of about 0.5 to 30 parts by weight, based on 100 parts by weight of the mixture of the first and second acrylic monomer. If the content of the filler is less than 0.5 parts by weight, a porous structure capable of providing a cushion property may not be formed within the blocking pad layer. Also, if the content of the filler exceeds 30 parts by weight, excess in pore formation may cause lowering of the strength of the blocking pad layer.

The fumed silica may provide the blocking pad layer of the resultant gasket with an adhesive property, and increase a shear force. In addition to the fumed silica functioning in this way, materials having similar properties to the fumed silica, such as titanium oxides and aluminum hydroxides, may be included.

There is no particular limitation on the particle diameter of the fumed silica-type filler, but a particle diameter of about 50 nm to 1 micron is preferred. If the particle diameter of the filler is less than 50 nm, it is impossible to obtain sufficient strength, and the amount of the filler to be used increases. Also, if the particle diameter of the filler exceeds 1 micron, surface defects of the blocking pad layer may occur.

The fumed silica-type filler may have, but not limited to, a content of about 0.1 to 100 parts by weight, based on 100 parts by weight of the mixture of the first and second acrylic monomer. If the content of the filler is less than 0.1 parts by weight, it is impossible to provide a proper reinforcing adhesive property or increase a shear force. Also, if the content of the filler exceeds 100 parts by weight, foreign substances may occur at a cut section when the pad is cut.

In addition to the above components, the acrylic polymer resin composition constituting the blocking pad layer may further include a pigment. By including the pigment in the acrylic polymer resin composition, the resultant gasket manufactured using the composition can perform a function of blocking external light beams from entering an image display module, or a function of intercepting light leakage when an image display module or frames is/are bent.

The pigment is divided into an organic pigment and an inorganic pigment, and the content and property of a pigment included in the composition varies according to the color of the pigment, which leads to a change in the resultant gasket's function of blocking light influx/leakage. In consideration of this, it is preferred to use a pigment of a suitable color. According to an embodiment of the present disclosure, a black pigment, the main component of which is an acrylic polymer resin, is used.

There is no particular limitation on the average particle size (particle diameter) of the pigment, but a particle size of about 10 microns or less is preferred so that the resultant gasket can block light influx/leakage.

The pigment has, but not limited to, a content of about 0.3 to 5 parts by weight, based on 100 parts by weight of the mixture of the first and second acrylic monomer. If the content of the pigment is less than 0.3 parts by weight, light leakage cannot be adequately prevented. Also, if the content of the pigment exceeds 5 parts by weight, the pigment may not be adequately cured when the acrylic polymer resin composition is cured by UV irradiation.

The aforementioned acrylic polymer resin composition may be prepared by, but not limited to, the steps of mixing and partially polymerizing a first acrylic monomer with a second acrylic monomer to thereby form syrup; and mixing the syrup with a urethane acrylate oligomer and a filler.

The partial polymerization of the first and second monomers may be performed by light irradiation, preferably UV irradiation, under conditions substantially free of oxygen. In this way, it is possible to obtain syrup having a viscosity of about 500 to 20,000 cps. In some cases, a photoinitiator may be used.

Herein, the conditions free of oxygen may be achieved by an oxygen concentration of 100 ppm or less and/or an inert atmosphere in which argon gas, helium gas, krypton gas, or xenon gas prevails, a nitrogen gas atmosphere, a hydrogen gas atmosphere, etc.

Also, the light irradiation is preferably conducted at a light intensity of about 3 to 10 mW/cm². If the light intensity is less than 3 mW/cm², the reaction of the monomers may not be initiated. Also, if the light intensity exceeds 10 mW/cm², a gel may be formed. According to an embodiment of the present disclosure, the intensity of UV rays is about 7 mW/cm².

There is no particular limitation on the temperature of the partial polymerization. For example, the partial polymerization may be conducted at a temperature of about 17 to 20° C.

Examples of the photoinitiator include, but not limited to, benzyl-dimethylketal, 2,4,6-trimethylbenzoyldiphenylphosphine oxide, bis(2,4,6-trimethylbenzoyl)phenylphosphine oxide, α,α-methoxy-α-hydroxyacetophenone, 2-benzoyl-2(dimethylamino)-1-[4-(4-morphonyl)phenyl]-1-butanone, 2,2-dimethoxy 2-phenyl acetophenone, etc.

The blocking pad layer may be laminated on one side of the support layer. The support layer may be a polyethylene terephthalate (PET) film, and can support the resultant gasket. Also, if necessary, a PET film containing a pigment may be used as the support layer, which not only supports the resultant gasket, but also can blocking external light beams from entering an image display module, and simultaneously intercept light leakage when an image display module or/and frames is/are bent by external forces. According to an embodiment of the present disclosure, the support layer may be a PET film containing a black pigment.

The support layer may have, but not limited to, a thickness of about 25 to 100 microns. According to an embodiment of the present disclosure, the thickness of the support layer is about 50 microns.

The adhesive layer comprises an adhesive polymer resin and may be laminated on the other side of the support layer. By including the adhesive layer in the gasket in this way, the gasket can be applied to the display apparatus without using a separate tape or adhesive.

The adhesive polymer resin constituting the adhesive layer is not particularly limited. According to an embodiment of the present disclosure, an acrylic polymer resin may be used as the adhesive polymer resin.

A example of the acrylic polymer resin includes a polymer in which (meth)acrylic acid ester monomer having an C₁ to C₁₂ alkyl group is copolymerized with a polar monomer copolymerizable with the above monomer.

Examples of the (meth)acrylic acid ester monomer include, but not limited to, butyl(meth)acrylate, hexyl(meth)acrylate, n-octyl(meth)acrylate, isooctyl(meth)acrylate, 2-ethylhexyl(meth)acrylate, isononyl(meth)acrylate, etc.

Also, examples of the polar monomer copolymerizable with the (meth)acrylic acid ester monomer include, but not limited to, a monomer containing a carboxyl group, such as (meth)acrylic acid, maleic acid, and fumaric acid, and a monomer containing nitrogen, such as acrylamide, N-vinyl pyrrolidone, and N-vinyl caprolactam. Such a polar monomer functions to provide the adhesive layer with cohesion and improve adhesive strength.

For the adhesive polymer resin, there is no particular limitation on the mixing ratio of the (meth)acrylic acid ester monomer and the polar monomer, but they may have a weight ratio of 99-80:1-20. In such a range, the acrylic polymer resin can exhibit adhesive strength required as an adhesive.

The thickness of such an adhesive layer 3 made of the adhesive polymer resin may be selected within, but not limited to, a range of about 1 to 200 microns.

Also, in some embodiments, the gasket may further include a release film on the other side of the adhesive layer, on one side of which the support layer is laminated. The release film covers one side of the adhesive layer to thereby protect the adhesive layer from external process environments, and is removed from the adhesive layer when the gasket is applied to the display apparatus later on, thereby enabling the gasket to be normally attached to the display apparatus.

The release film functioning in this way may be a film coated with a release layer thereon, or a film having low surface energy. Examples of the release film include a polyethylene film, a polypropylene film, a polyethylene terephthalate (PET) film, etc.

A gasket that includes the blocking pad layer, the support layer, and the adhesive layer, and if necessary, includes the release film, as described above, may be manufactured in various ways.

According to an example of the present disclosure, the gasket is manufactured by a method including the steps of applying the aforementioned acrylic polymer resin composition onto one side of the prefabricated support layer, and then curing the acrylic polymer resin composition to thereby form the blocking pad layer; and applying adhesive polymer resin syrup onto the other side of the support layer with the blocking layer laminated on its one side, and then curing the adhesive polymer resin syrup to thereby form the adhesive layer. Here, the step of curing the acrylic polymer resin composition may include a first step of irradiating ultraviolet rays of about 2 to 10 mW/cm²; and a seconds step of irradiating ultraviolet rays of about 30 to 50 mW/cm².

According to another example of the present disclosure, the gasket is manufactured by a method including the steps of applying the aforementioned acrylic polymer resin composition onto one side of the prefabricated support layer, and then curing the acrylic polymer resin composition to thereby form the blocking pad layer; and disposing adhesive polymer resin syrup between the release film and the support layer with the blocking layer laminated on its one side, and then curing the adhesive polymer resin syrup to thereby form the adhesive layer 3. Here, the step of curing the acrylic polymer resin composition may include a first step of irradiating ultraviolet rays having an intensity of about 2 to 10 mW/cm²; and a seconds step of irradiating ultraviolet rays having an intensity of about 30 to 50 mW/cm².

1) First of all, the blocking pad layer may be manufactured by applying the acrylic polymer resin composition onto one side of the prefabricated support layer and then curing the acrylic polymer resin composition.

A way to cure the acrylic polymer resin composition applied onto the support layer may employ any method known in the relevant art. According to an embodiment of the present disclosure, the acrylic polymer resin composition applied onto the support layer is cured by UV irradiation.

To be specific, the acrylic polymer resin composition may be cured in two steps, that is, a first step of irradiating UV rays having an intensity of about 2 to 10 mW/cm²; and a second step of irradiating UV rays having an intensity of 30 to 50 mW/cm² to thereby remove residual monomers. With regard to this, the first UV irradiation step may be performed through the steps of irradiating UV rays having an intensity of about 2 to 4 mW/cm²; irradiating UV rays having an intensity of about 4 to 6 mW/cm²; and irradiating UV rays having an intensity of about 7 to 9 mW/cm².

For example, by irradiating the acrylic polymer resin composition with UV rays having an intensity of about 3.1 mW/cm² for about 30 seconds, with UV rays having an intensity of about 5 mW/cm² for about 60 seconds, with UV rays having an intensity of about 8 mW/cm² for about 30 seconds, and then with UV rays having an intensity of about 40 mW/cm² for about 5 seconds, the acrylic polymer resin composition can be cured to form the blocking pad layer. However, it is preferred to select such UV irradiation conditions in consideration of the type of a display apparatus to which the resultant gasket is applied, and required properties.

2) Subsequently, the adhesive layer may be formed in various ways. For example, a way to form the adhesive layer includes (a) a method of applying the adhesive polymer resin syrup onto the other side of the support layer with the blocking pad layer laminated on its one side, and then curing the adhesive polymer resin syrup; (b) a method of disposing the adhesive polymer resin syrup between the release film and the support layer with the blocking pad layer laminated on its one side, and then curing the adhesive polymer resin syrup, and others.

However, in the case of forming the adhesive layer by method (a), a step of laminating the release film on the other side of the adhesive layer with the support layer laminated on its one side may be further included. Herein, a laminating roller method may be used as a way to laminate the release film.

Further, in some embodiments, the present disclosure provides a display apparatus including frames; and the above at least one gasket disposed/fixed on surfaces of the frames.

Referring to FIG. 4, according to an embodiment of the present disclosure, in a display apparatus including a front frame 101; a rear frame 102; and an image display module 103 disposed between the front and rear frames, a gasket 10 may be disposed/fixed on the edge surface of the front frame 101 and/or the edge surface of the rear frame 102 (not shown). In some cases, the gasket 10 may be disposed/fixed on the edge surface of the image display module 103 (not illustrated), as well as the front and rear frames 101, 102. Alternatively, in the case of a display apparatus further including a guide frame 104 around the edge of the rear frame 102, the above gasket 10 may be disposed/fixed on the surface of the guide frame 104 (see FIG. 4).

The display apparatus 100 is an apparatus for displaying images in electronic equipment, and its examples include LCD, PDP, LED, CRT, etc.

By applying the aforementioned gasket 10 to the display apparatus 100, the display apparatus can be protected from external shocks and vibrations, and external light beams cannot enter the image display module. Additionally, even when the image display module or/and the frames is/are bent by external forces, light generated within the display apparatus cannot leak outside of the display apparatus.

Reference will now be made in detail to exemplary examples and comparative examples. It is to be understood that the following examples are illustrative only, and the scope of the present disclosure is not limited thereto.

### EXAMPLE 1

1-1. Preparation of Acrylic Polymer Resin Composition

About 90 parts by weight of isooctylacrylate (IOA) (IOA monomer, 3M Company) as a first acrylic monomer and about 10 parts by weight of acrylic acid (AA) (AA monomer, LG Chemical) as a second acrylic monomer were put into a glass reactor. About 0.04 parts by weight of benzyl dimethylketal (BDK) (Irgacure 651, Ciba Specialty Chemical) as a photoinitiator was added thereto. Subsequently, the mixture of the monomers and the photoinitiator was irradiated with UV rays having an intensity of about 7 mW/cm² at a temperature of about 17° C. under a nitrogen gas atmosphere (concentration of oxygen contained in atmosphere: 100 ppm) to partially polymerize the monomers. As a result of this, syrup having a viscosity of about 2,000 cps was obtained.

About 30 parts by weight of urethane acrylate oligomer (M-1600, ToaGosei Company), about 10 parts by weight of isooctylacrylate (IOA, 3M Company), about 4 parts by weight of glass bubble (G15K, 3M Company), about 2 parts by weight of fumed silica (R-972, Daeguas), and about 1 part by weight of black pigment powder made of an acrylic polymer resin (GR-800BK, Negami Chemical Industrial) were added to about 100 parts by weight of the above-obtained syrup having a viscosity of 2,000 cps. This mixture was stirred to prepare an acrylic polymer resin composition.

1-2. Manufacture of Gasket

One side of a black polyester film (SB00, SKC) was coated with the acrylic polymer resin composition prepared in Example 1-1 by a thickness of about 350 microns, and then the acrylic polymer resin composition was cured by UV irradiation under the following conditions to form a blocking pad layer on the film. Subsequently, an acrylic adhesive (A74010, 3M Company) was applied onto the other side of the black polyester film by a thickness of about 100 microns to manufacture the inventive gasket. The surface of the so-manufactured gasket is illustrated in FIG. 6(a).

*UV Irradiation Conditions*

Irradiating UV rays having an intensity of about 3 mW/cm² for 30 seconds followed by irradiating UV rays having an intensity of about 5 mW/cm² for 60 seconds followed by irradiating UV rays having an intensity of about 8 mW/cm² for 30 seconds followed by irradiating UV rays having an intensity of about 40 mW/cm² for 10 seconds

### EXAMPLE 2

An acrylic polymer resin composition was prepared in the same manner as described in Example 1-1, and then a gasket was manufactured in the same manner as described in Example 1-2, except that about 10 parts by weight of urethane acrylate oligomer (M-1600, ToaGosei Company), about 10 parts by weight of isooctylacrylate (IOA, 3M Company), about 7 parts by weight of glass bubble (G15K, 3M Company), about 2 parts by weight of fumed silica (R-972, Daeguas), and about 1 part by weight of black pigment powder made of an acrylic polymer resin (GR-800BK, Negami Chemical Industrial) were added to about 100 parts by weight of the syrup having a viscosity of 2,000 cps, obtained in Example 1-1. The surface of the so-manufactured gasket is illustrated in FIG. 6(b).

### EXAMPLE 3

An acrylic polymer resin composition was prepared in the same manner as described in Example 1-1, and then a gasket was manufactured in the same manner as described in Example 1-2, except that about 20 parts by weight of urethane acrylate oligomer (M-1600, ToaGosei Company), about 30 parts by weight of isooctylacrylate (IOA, 3M Company), about 5.5 parts by weight of glass bubble (G15K, 3M Company), about 2 parts by weight of fumed silica (R-972, Daeguas), and about 1 part by weight of black pigment powder made of an acrylic polymer resin (GR-800BK, Negami Chemical Industrial) were added to about 100 parts by weight of the syrup having a viscosity of 2,000 cps, obtained in Example 1-1. The surface of the so-manufactured gasket is illustrated in FIG. 6(c).

### EXAMPLE 4

An acrylic polymer resin composition was prepared in the same manner as described in Example 1-1, and then a gasket was manufactured in the same manner as described in Example 1-2, except that about 30 parts by weight of urethane acrylate oligomer (M-1600, ToaGosei Company), about 50 parts by weight of isooctylacrylate (IOA, 3M Company), about 7 parts by weight of glass bubble (G15K, 3M Company), about 2 parts by weight of fumed silica (R-972, Daeguas), and about 1 part by weight of black pigment powder made of an acrylic polymer resin (GR-800BK, Negami Chemical Industrial) were added to about 100 parts by weight of the syrup having a viscosity of 2,000 cps, obtained in Example 1-1. The surface of the so-manufactured gasket is illustrated in FIG. 6(d).

### EXAMPLE 5

An acrylic polymer resin composition was prepared in the same manner as described in Example 1-1, and then a gasket was manufactured in the same manner as described in Example 1-2, except that about 10 parts by weight of urethane acrylate oligomer (M-1600, ToaGosei Company), about 50 parts by weight of isooctylacrylate (IOA, 3M Company), about 4 parts by weight of glass bubble (G15K, 3M Company), about 2 parts by weight of fumed silica (R-972, Daeguas), and about 1 part by weight of black pigment powder made of an acrylic polymer resin (GR-800BK, Negami Chemical Industrial) were added to about 100 parts by weight of the syrup having a viscosity of 2,000 cps, obtained in Example 1-1. The surface of the so-manufactured gasket is illustrated in FIG. 6(e).

Anti-slip Test Procedure

In order to measure the anti-slip property of the inventive gasket, the flowing experiments were conducted:

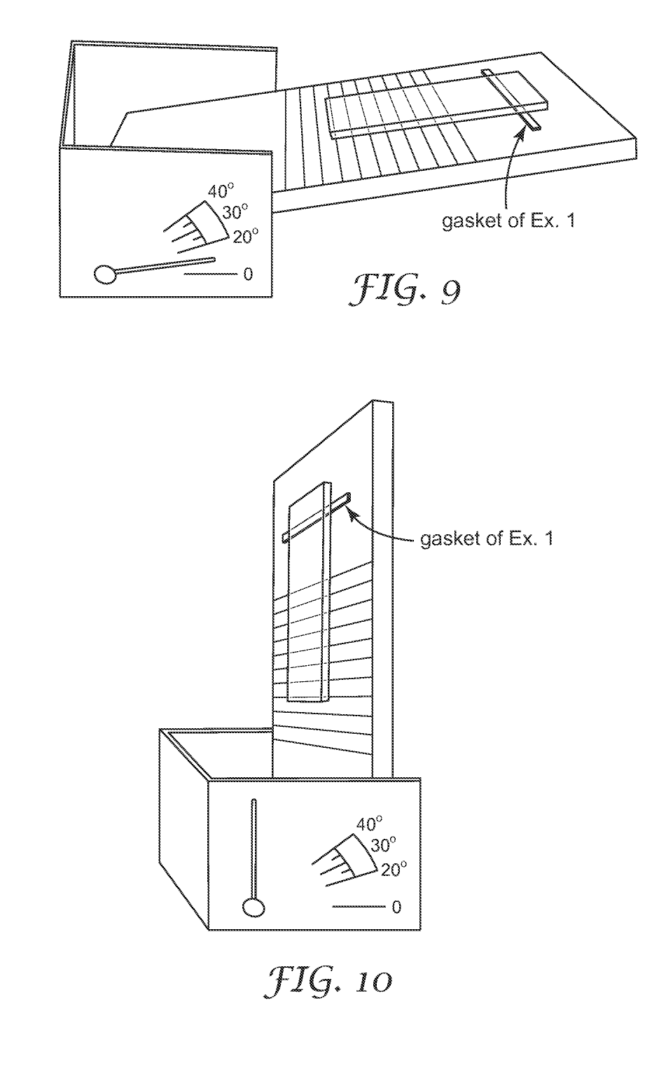

1) Anti-Slip Test Procedure 1. The gasket manufactured in Example 1 is cut into a strip having a width of 2 mm and a length of 40 mm. The strip was horizontally attached to the surface of an inclination adjusting device while being opposite to the ground. With regard to this, the strip was attached such that the adhesive layer of the strip came into contact with the surface of the inclination adjusting device. Subsequently, a glass plate having a weight of 80 g was disposed on the surface of the strip, and then whether or not the glass plate slips down was measured while the inclination of the inclination adjusting device was changed from 0° to 40°. (See FIG. 9.)

2) Anti-Slip Test Procedure 2. The gasket manufactured in Example 1 is cut into a strip having a width of 2 mm and a length of 40 mm. The strip was horizontally attached to the surface of an inclination adjusting device while being opposite to the ground. With regard to this, the strip was attached such that the adhesive layer of the strip came into contact with the surface of the inclination adjusting device. Subsequently, a glass plate having a weight of 80 g was disposed on the surface of the strip, and then whether or not the glass plate slips down was measured when the inclination of the inclination adjusting device was 90°. (See FIG. 10.)

As a result of the experiments, the glass plate did not slip down.

1. A gasket comprising:
a support layer;
a blocking pad layer on one side of the support layer and made of an acrylic polymer resin composition; and
an adhesive layer on the other side of the support layer and made of an adhesive polymer resin,
wherein the acrylic polymer resin composition comprises a urethane acrylate oligomer; a first acrylic monomer; a second acrylic monomer having a higher glass transition temperature than the first acrylic monomer; and a filler.

2. The gasket as claimed in claim 1, wherein the blocking pad layer comprises a surface thereof with a plurality of continuous or discontinuous concavo-convex projection patterns.

3. The gasket as claimed in claim 2, wherein the projection patterns have a height of 0.3 to 100 microns.

4. The gasket as claimed in claim 1, which has adhesive has sufficient strength to fix a glass plate with a weight of 80 g in an inclination of 90° without any movement when the glass plate is disposed on a strip of the gasket, having an area of 2 mm by 40 mm as measured according to Anti-Slip test Procedure 2.

5. The gasket as claimed in claim 1, wherein the urethane acrylate oligomer has a number average molecular weight of 5,000 to 100,000.

6. The gasket as claimed in claim 1, wherein the first acrylic monomer comprises an acrylic monomer having a C₆ to C₁₂ alkyl group.

7. The gasket as claimed in claim 1, wherein the first acrylic monomer has a glass transition temperature of −80 to 0° C., and the second acrylic monomer has a glass transition temperature of 60 to 120° C.

8. The gasket as claimed in claim 1, wherein the acrylic polymer resin composition comprises the first and second acrylic monomers in a weight ratio of 95-60:5-40.

9. The gasket as claimed in claim 1, wherein the acrylic polymer resin composition comprises:
60 to 95 parts by weight of the first acrylic monomer;
5 to 40 parts by weight of the second acrylic monomer;
5 to 80 parts by weight of the urethane acrylate oligomer; and
0.1 to 100 parts by weight of the filler,
based on 100 parts by weight of the mixture of the first and second acrylic monomer.

10. The gasket as claimed in claim 1, wherein the support layer comprises a polyethylene terephthalate film.

11. The gasket as claimed in claim 1, wherein the adhesive polymer resin comprises an acrylic polymer resin.

12. The gasket as claimed in claim 1, further comprising a release film on the side of the adhesive layer opposite the support layer.

13. A display apparatus comprising:
an image display module;
frames; and
the gasket as claimed in claim 1, which is disposed on a partial surface of the image display or part surfaces of the frames.

14. A method of manufacturing a gasket, the method comprising the steps of:
applying an acrylic polymer resin composition onto one side of a support layer;
curing the acrylic polymer resin composition applied onto the support layer to thereby form a blocking pad layer; and
applying adhesive polymer resin syrup onto the other side of the support layer with the blocking layer laminated on the one side thereof and then curing the adhesive polymer resin syrup to thereby form an adhesive layer,
wherein the step of curing the acrylic polymer resin composition comprises a first step of irradiating ultraviolet rays having an intensity of 2 to 10 mW/cm²; and a seconds step of irradiating ultraviolet rays having an intensity of 30 to 50 mW/cm².

15. The method as claimed in claim 14, wherein the first step of irradiating ultraviolet rays comprises the steps of:
irradiating ultraviolet rays having an intensity of 2 to 4 mW/cm²;
irradiating ultraviolet rays having an intensity of 4 to 6 mW/cm²; and
irradiating ultraviolet rays having an intensity of 7 to 9 mW/cm².
